(19) United States
(12) Patent Application Publication
(10) Pub. No.: US 2011/0147910 A1
(43) Pub. Date: Jun. 23, 2011

(54) METHOD FOR STACKING DIE IN THIN, SMALL-OUTLINE PACKAGE

(75) Inventors: Tracy V. Reynolds, Boise, ID (US); Mark S. Johnson, Meridian, ID (US)

(73) Assignee: MICRON TECHNOLOGY, INC., Boise, ID (US)

(21) Appl. No.: 12/643,796

(22) Filed: Dec. 21, 2009

(51) Int. Cl. H01L 25/065; H01L 21/98

(52) U.S. Cl. 257/686; 438/109; 257/690; 257/E21.705; 257/E21.499; 257/E23.141; 257/E25.013

(57) ABSTRACT

Several embodiments of microelectronic device packaging configurations with lead frames without downsets are disclosed herein. In one embodiment, the configuration includes a pair of microelectronic dies with active surfaces facing one another, and a lead frame positioned between the dies. The lead frame has no downset and extends from between the dies and protrudes out of an encapsulant material. In one embodiment the lead frame is connected to both an upper and a lower die. In other embodiments, the lead frame is connected to a first die by wirebonds and is not connected to a second die. The first and second die may be connected to one another by interconnects such as solder ball interconnects.

### TECHNICAL FIELD

The present disclosure is related to a method and apparatus for packaging a stacked microelectronic die in a thin, small-outline package.

### BACKGROUND

Microelectronic devices are consistently becoming more powerful and smaller because there is intense market pressure to produce reliable, high-performance electronic products in small sizes (e.g., portable computers, cell phones, smart phones, music/video players, etc.). As such electronic products shrink, the available space for microelectronic devices within the electronic products also decreases. Standards for sizing the microelectronic devices provide useful guidelines to ensure interoperability between manufacturers and to ease communication between vendors and manufacturers. One standard governing semiconductors and other solid-state equipment is set forth by the Joint Electron Device Engineering Council (“JEDEC”). The JEDEC standard relates to the size, shape, and other features of microelectronic devices and packaging. Although the JEDEC standard provides the benefits of interoperability, a consistent challenge is to maximize the capabilities of the microelectronic device within the package sizes defined by the standard.

FIG. 1 illustrates a stacked die package configuration 100 governed by a standard, such as a JEDEC standard, that includes upper and lower dies 102 and 104, respectively, which are stacked and configured to pass electrical signals between one another. In some configurations, the dies 102 and 104 have active faces 106 and 108 that face each other in the stacked configuration. In other configurations, the active faces 106 and 108 face the same direction and are electrically connected by through-silicon vias or other means. The stacked dies 102 and 104 are connected to a lead frame 110 that has a number of leads configured to be connected to external holes or surface contacts of a host device (not shown). Wire bonds 115 may connect individual leads of the lead frame 110 to corresponding bond pads of the dies 102 or 104. After the dies 102 and 104 are secured to the lead frame 110 and/or each other so that contacts of the dies 102 and 104 are electrically connected to corresponding leads, an encapsulant 112 is molded around the dies 102 and 104 and a portion of the lead frame 110. A distal portion of the lead protrudes from the encapsulant 112 to connect to the host device. Within the encapsulant 112, the lead frame 110 has a downset 113 defined by a sloping portion outside of the lower die 104. The downset 113, more specifically, is formed by a first curved portion 119a and a second curved portion 119b of each lead within the encapsulant 112. The first curved portion 119a reduces the vertical dimension (or thickness) of the package by eliminating empty space below the second die 104 that would exist without the downset.

Standards, such as the JEDEC standards, govern the size and shape of the encapsulant 112 and the package 100. The standards regulate a joint area 114 between the lead frame 110 and the encapsulant 112, and the thicknesses of critical dimensions 116, 117, and 118 of the encapsulant 112 at various positions around the dies 102 and 104. The downset 113 limits the size of the dies 102 and 104 within the parameters of a given standard package size because conventional downsets 113 cause the lower die 104 to be closer to a lower portion or sidewall of the encapsulant 112. The dies 102 and 104, more specifically, must be small enough to maintain a minimum of one or more of the critical dimensions 116, 117 and/or 118 of the encapsulant 112. Limiting the lateral dimensions of the dies 102 and 104 necessarily limits the capabilities of the device because fewer components can fit in the package 100 and still meet the standards.

### BRIEF DESCRIPTION OF THE DRAWINGS

FIG. 1 is a partially schematic cross-sectional view of a microelectronic device in accordance with the prior art.

FIG. 2 is a partially schematic cross-sectional view of a microelectronic device in accordance with the new technology.

FIG. 3 is a partially schematic cross-sectional view of a microelectronic device in accordance with the new technology.

### DETAILED DESCRIPTION

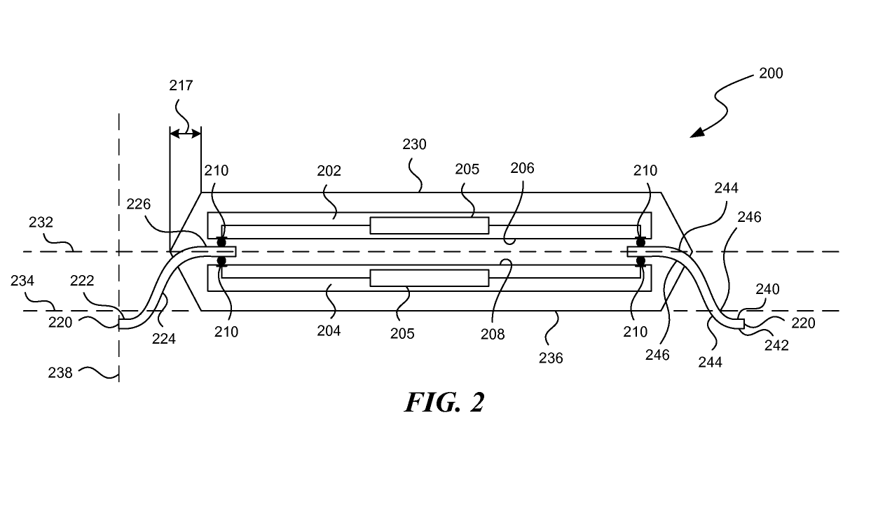

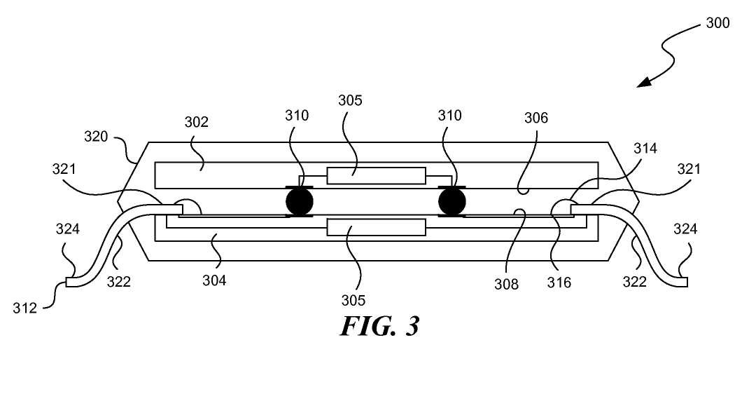

Specific details of several embodiments of the new technology are described below with reference to microelectronic device configurations and associated methods of manufacturing. Typical microelectronic device packages include microelectronic circuitry or components (e.g., integrated circuitry), micro-fluidic devices, and other components manufactured on microelectronic substrates. Micromachines and micromechanical devices are included within this definition because they are manufactured using technology similar to that used in the fabrication of integrated circuits. The term “microfeature substrate” or “die” is used throughout to include semiconductor substrates and other types of substrates upon which and/or in which semiconductor devices or other types of microelectronic devices or micromechanical devices and other features are fabricated. Suitable materials for dies can include semiconductor pieces (e.g., doped silicon wafers or gallium arsenide wafers), nonconductive pieces (e.g., various ceramic substrates), or conductive pieces. Microfeature dies can also include one or more layers (e.g., conductive, semiconductive, and/or dielectric) that are situated upon and/or within one another. These layers can include or form a wide variety of electrical components, mechanical components, and/or systems of such components (e.g., integrated circuits, memory devices, processors, imagers, light emitting diodes, micromechanical systems, etc.). The term “surface” can encompass planar and nonplanar surfaces of a semiconductor substrate with or without patterned and nonpatterned features. A person skilled in the relevant art will also understand that the new technology may have additional embodiments and that the new technology may be practiced without several of the details of the embodiments described below with references to FIGS. 2 and 3.

In several embodiments of the new technology, a microelectronic device includes a first die comprising an integrated circuit, a first active face, and an inactive surface opposite the first active face. The first active face includes a plurality of first terminals electrically connected to the integrated circuit of the first die. The microelectronic device also includes a second die comprising an integrated circuit and second active face. The second active face includes a plurality of second terminals electrically connected to the integrated circuit of the second die. The first die and the second die are positioned with the first active face and the second active face facing one another. The microelectronic device also includes an encapsulant molded around the first die, the second die, and a lead frame. The lead frame has a proximal portion positioned between the first active face and the second active face and electrically connected to at least one of the first die and the second die. The lead frame also includes a transition portion protruding from the encapsulant and sloping toward the first die, and a distal portion configured to connect with a host device.

In still other embodiments, a method for packaging a microelectronic device in accordance with the new technology includes mounting a first die to a lead frame, and mounting a second die to at least one of the first die or the lead frame. The first die and the second die have active surfaces that face one another. The method further includes encapsulating the first die, the second die, and at least a portion of the lead frame, wherein the lead frame extends from between the first active surface and the second active surface and protrudes from the encapsulant.

FIG. 2 illustrates embodiments of a specific microelectronic device 200 that includes a first die 202 and a second die 204 in accordance with the new technology. The dies can have electronic components 205, for example, integrated circuits. Other embodiments of the device 200 can include more than two dies, but for purposes of explanation a stacked configuration of only two dies 202 and 204 is shown. The first and second dies 202 and 204 have first and second active surfaces 206 and 208, respectively, and in some embodiments the first and second dies 202 and 204 are positioned such that the first and second active faces 206 and 208 face one another (known as a “face-to-face” configuration). The first and second active faces 206 and 208 can each have a redistribution layer (not shown) or other structure that includes electrical connectors 210 for electrically connecting the components 205 to a lead frame or circuit board. The interconnecting regions 210, for example, can be bond-pads or other electrical terminals through which electrical signals and voltages can be transmitted to and/or from the components 205.

The microelectronic device 200 can also have a lead frame 220 having a distal portion 222, a transition portion 224, and a proximal portion 226 relative to the first and second dies 202 and 204. The proximal portion 226 (or proximal end 226) of the lead frame 220 is positioned between the dies 202 and 204 and electrically connected to the first die 202 and/or the second die 204. An encapsulant 230 is molded or otherwise formed around the dies 202 and 204 and the proximal portion 226 of the lead frame 220. In some embodiments a section of the transition portion 224 is also positioned within the encapsulant 230. The proximal portion 226 interior to the encapsulant has no downset; rather, the lead frame 220 extends from between the dies 202 and 204 laterally outwardly and continues outside the encapsulant 230. In some embodiments, a section of the proximal portion 226 of the lead frame 220 extends from between the dies 202 and 204 in a medial plane 232 generally parallel to the planes defined by the active faces 206 and 208. The proximal portion 226 of the lead frame 220 can extend in the medial plane 232 almost until the exterior surface of the encapsulant. The transition portion 224 curves away from the medial plane 232 and continues beyond a distal plane 234 defined generally by a lower surface 236 of the encapsulant 230. As shown in FIG. 2, for example, a single curve between the proximal portion 226 and the transition portion 224 is within the encapsulant 230, and the transition portion 224 slopes monotonically away from the medial plane 232 defined by the proximal portion 226 between the dies 202 and 204. The distal portion 222 can slope away from the transition portion 224 and into the distal plane 234. In other embodiments, the distal portion 222 can be shaped into a plane 238 generally perpendicular to the medial plane 232 and the distal plane 234 to fit into through-hole connectors of a host device. In these embodiments, no portion of the lead frame 220 is more distant from the distal plane 234 than the distal portion 222.

Several embodiments of the lead frame 220 can accordingly have a first surface 240 and a second surface 242, and each of the surfaces 240 and 242 can have one convex portion 244 and one concave portion 246. For the first surface 240, the convex portion 244 is nearer to the encapsulant 230 than the concave portion 246; for the second surface 242, the concave portion 246 is nearer to the encapsulant 230 than the convex portion 244. In some embodiments, the convex portion 244 and concave portion 246 have generally the same radius of curvature. In other embodiments, these portions can have compound curvatures along the length of the lead frame 220. As shown in FIG. 2, the first die 202 is positioned to one side of the proximal portion 226 and the second die 204 is positioned to another side of the proximal portion 226. The proximal portion 226 can be electrically and/or mechanically connected to each of the first and second dies 202 or 204 by electrical connectors 210 such as solder balls.

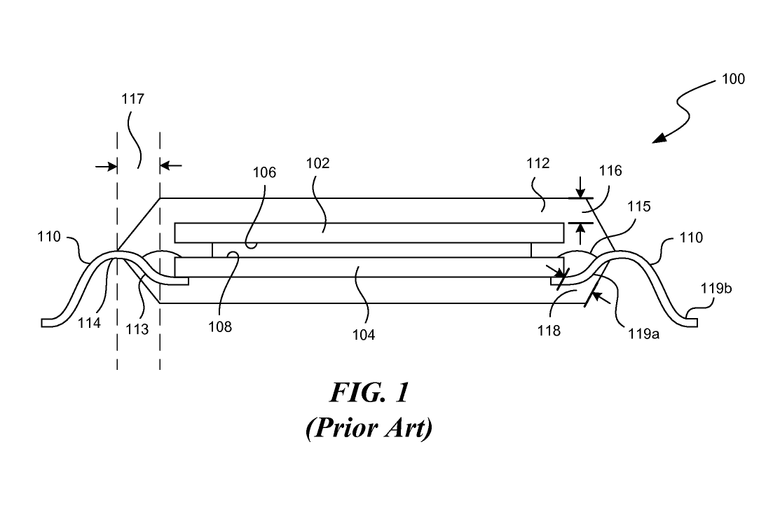

Several of the embodiments in accordance with the new technology provide a package structure that allows the dies of a microelectronic device to be bigger and therefore contain more components than conventional systems. As explained above, conventional lead frames with downsets limit the lateral dimension of the dies because the space occupied by the downset reduces the space within a given package size for the dies; this in turn limits the capabilities of the microelectronic device because the smaller dies have fewer components. Several embodiments of the configuration shown in FIG. 2 provide a package in which the dies 202 and 204 can be larger laterally than conventional packages and still meet the JEDEC standards. For example, by positioning the proximal portion 226 of the lead frame 220 between the dies 202 and 204, and by eliminating the downset from the lead frame 220, the dimension 117 shown in FIG. 1 is substantially larger than a corresponding dimension 217 shown in FIG. 2. Accordingly, the microelectronic device 200 provides more space for the dies within a given package that conforms to the JEDEC standards.

FIG. 3 illustrates an alternate embodiment of a microelectronic device 300 according to the new technology. Again, for simplicity, only two die are shown. However, more than two may be included in any given package. The microelectronic device 300 has a first die 302 and a second die 304, and each of the dies 302 and 304 can contain an embedded component 305 such as an integrated circuit or other electric component. The dies 302 and 304 include a first active face 306 and a second active face 308, respectively, comprising a plurality of electrical terminals connected to the embedded circuitry and providing a means to transmit an electrical signal. The dies 302 and 304 are arranged such that the first active face 306 faces the second active face 308. In one embodiment, the active faces 306 and 308 have a redistribution layer (not shown) through which electrical signals and voltages are transmitted to and from the dies 302 and 304. The microelectronic device 300 may also contain a ball grid array comprising interconnecting elements 310 such as solder ball interconnects or bump connectors. The interconnecting elements 310 can be positioned between the first die 302 and the second die 304 and reflowed to electrically and mechanically connect the first die 302 to the second die 304. In other embodiments, both dies 302 and 304 have a solder ball in place, and when they are brought together and reflowed the two solder balls join together to form the interconnecting elements 310. Although FIG. 3 shows two interconnecting elements 310, a different number and/or configuration of interconnecting elements 310 can be used.

Selected embodiments of the microelectronic device 300 can include a lead frame 312 attached to the active surface of one of the first die 302 or the second die 304. The lead frame 312 comprises several electrically conductive lines between terminals 316 on the dies 302 and 304 and a host component. In some embodiments, the lead frame 312 can be positioned adjacent to and/or connected to the first die 302; in other embodiments the lead frame 312 can be positioned adjacent to and/or connected to the second die 304. Or, in still other embodiments, the lead frame 312 can be attached to both the first die 302 and the second die 304. The lead frame 312 can be connected to the dies 302 or 304 electrically, mechanically, or both mechanically and electrically.

When the lead frame 312 is attached to the second die 304, the microelectronic device 300 can include wirebonds 314 that extend from the lead frame 312 to corresponding terminals 316 on the second die 304. The lead frame 312 can have sufficient thickness to operate as desired without permitting the lead frame 312 or the wirebonds 314 to contact the first die 302. Also, the interconnecting elements 310 can be configured to space the dies 302 and 304 apart from each other by a sufficient distance to position the lead frame 312 and the wirebonds 314 between the first die 302 and the second die 304. The dies 302 and 304, the interconnecting elements 310, the lead frame 312, and the wirebonds 314 together provide many electrical paths between the dies 302 and 304 and an external host device. The device also has an encapsulant 320 molded or otherwise formed over the dies 302 and 304, the wirebonds 314, and at least a portion of the lead frame 312.

According to several embodiments, the microelectronic device 300 includes a lead frame 312 that does not have a downset. The lead frame 312 includes individual leads that have a proximal portion 321, a transition portion 322, and a distal portion 324 that are FIG. 2. As such, the lead frame 312 can have many of the same features and advantages described above with reference to the lead frame 220 shown in FIG. 2. The lead frame 312, for example, can have any shape defined by a JEDEC or other standard that eliminates the downset and allows the dies 302 and 304 to be larger than conventional devices.

In further embodiments, a microelectronic device includes a first die with a first active surface comprising a plurality of electric terminals, and a second die having a second active surface comprising a plurality of electric terminals. The first die and the second die are positioned face-to-face such that the first active surface faces the second active surface. The microelectronic device further includes an encapsulant surrounding the first die and the second die, and a lead frame protruding from the encapsulant. The lead frame is connected to at least one of the first die and the second die and has an interior portion within the encapsulant positioned between the first active surface and the second active surface. The interior portion has no downset.

In several other embodiments of the new technology, a microelectronic device comprises two dies that each have an active surface. The two dies are arranged such that the active surfaces face each other. The device also includes an encapsulant material that encases the two dies and a lead frame having leads with proximal portions positioned between the two dies and electrically connected to at least one of the dies. The lead frame has no downset such that the proximal portions of the leads extend laterally outwardly from between the two dies through the encapsulant material. In other embodiments, the new technology includes a microelectronic device comprising a first die having a first active surface and a second die having a second active surface. The first and second dies are positioned face-to-face such that the first and second active surfaces face one another. The device also includes an encapsulant surrounding the first and second dies, and a lead frame having leads with proximal portions connected to at least one of the first and second dies and distal portions extending from the encapsulant. The proximal portions of the leads are between the first and second active surfaces.

From the foregoing, it will be appreciated that specific embodiments of the invention have been described herein for purposes of illustration, but well-known structures and functions have not been shown or described in detail to avoid unnecessarily obscuring the description of the embodiments of the invention. Where the context permits, singular or plural terms may also include the plural or singular term, respectively. Unless the word “or” is associated with an express clause indicating that the word should be limited to mean only a single item exclusive from the other items in reference to a list of two or more items, then the use of “or” in such a list shall be interpreted as including (a) any single item in the list, (b) all of the items in the list, or (c) any combination of the items in the list.

Also, it will be appreciated that specific embodiments described above are for purposes of illustration and that various modifications may be made without deviating from the invention. Aspects of the disclosure described in the context of particular embodiments may be combined or eliminated in other embodiments. Further, while advantages associated with certain embodiments of the disclosure may have been described in the context of those embodiments, other embodiments may also exhibit such advantages, but not all embodiments need necessarily exhibit such advantages to fall within the scope of the disclosure. Accordingly, the present invention is not limited to the embodiments described above, which were provided for ease of understanding; rather, the invention includes any and all other embodiments defined by the claims.

I/We claim:

1. A microelectronic device, comprising:
a first die;
a second die;
an encapsulant molded around the first die and the second die; and
a lead frame comprising—
a proximal portion positioned between the first die and the second die and electrically connected to at least one of the first die and the second die;
a transition portion connected to the proximal portion and protruding from the encapsulant, wherein the transition portion slopes from the proximal portion toward the first die; and
a distal portion connected to the transition portion, wherein the distal portion is configured to connect with a host device.

2. The microelectronic device of claim 1 wherein:
the first die and the second die are generally parallel and define a medial plane between the first die and the second die, the medial plane being substantially equidistant from the first die and from the second die;
the proximal portion extends in the medial plane;
the proximal portion further comprises a proximal end positioned in the medial plane; and
the transition portion slopes away from the medial plane.

3. The microelectronic device of claim 2 wherein the distal portion and the proximal portion are generally parallel with the transition portion sloping between the proximal portion and the distal portion, and wherein the proximal portion has no downset.

4. The microelectronic device of claim 1 wherein the distal portion of the lead frame extends beyond an inactive surface of the first die.

5. The microelectronic device of claim 1 wherein the proximal portion of the lead frame is connected to at least one of the first die and the second die.

6. The microelectronic device of claim 1 wherein the proximal portion of the lead frame extends from between the first die and the second die in the medial plane and generally parallel to the first and second active surfaces to where the lead frame exits the encapsulant.

7. The microelectronic device of claim 1 wherein the transition portion slopes monotonically to the distal portion.

8. The microelectronic device of claim 1 wherein the lead frame has a single curve within the encapsulant.

9. The microelectronic device of claim 8 wherein the lead frame further comprises a single curve outside the encapsulant.

10. The microelectronic device of claim 1 wherein the lead frame further comprises:
a first surface with a convex portion and a concave portion, the convex portion being positioned between the encapsulant and the concave portion; and
a second surface with a convex portion and a concave portion, the concave portion being positioned between the encapsulant and the convex portion.

11. The microelectronic device of claim 10 wherein the proximal portion and the distal portion are generally straight, and wherein the transition portion contains the first surface and the second surface.

12. A microelectronic device, comprising:
a first die having a first active surface comprising a plurality of electric terminals;
a second die having a second active surface comprising a plurality of electric terminals, wherein the first die and the second die are positioned face-to-face such that the first active surface faces the second active surface;
an encapsulant surrounding the first die and the second die; and
a lead frame protruding from the encapsulant and connected to at least one of the first die and the second die, the lead frame having an interior portion within the encapsulant positioned between the first active surface and the second active surface, the interior portion having no downset.

13. The microelectronic device of claim 12 wherein the lead frame is connected to the first die by a wirebond.

14. The microelectronic device of claim 13 wherein a portion of the encapsulant insulates the second die from the wirebond and the lead frame.

15. The microelectronic device of claim 12 wherein the lead frame is connected to the first die by a wirebond and the first and second dies are interconnected by an array of reflowed conductive balls.

16. The microelectronic device of claim 12 wherein the interior portion has no more than one bend within the encapsulant.

17. The microelectronic device of claim 12 wherein the lead frame is connected to the first die and the second die by bump connectors.

18. A method for packaging a microelectronic device, comprising:
mounting a first die to a lead frame;
mounting a second die to at least one of the first die or the lead frame, the first die having a first active surface, and the second die having a second active surface, wherein the first active surface faces the second active surface; and
encapsulating the first die, the second die, and at least a portion of the lead frame with an encapsulant material, wherein the lead frame extends from between the first active surface and the second active surface and protrudes from the encapsulant material.

19. The method of claim 18, further comprising forming the lead frame into a proximal portion, a distal portion, and a transition portion between the proximal portion and the distal portion, wherein the transition portion slopes monotonically away from the proximal portion.

20. The method of claim 19 wherein forming the lead frame comprises forming a single bend between the proximal portion and the transition portion to be at least partially within the encapsulant before encapsulating the first die, the second die, and at least a portion of the lead frame.

21. The method of claim 20 wherein forming the lead frame further comprises forming a single bend between the transition portion and the distal portion outside of the encapsulant.

22. The method of claim 18, further comprising forming the lead frame into a sloped shape that slopes monotonically from a proximal portion to a distal portion.

23. The method of claim 18 wherein the first active surface defines a reference plane, the method further comprising forming the lead frame into a curved member including a proximal portion in the reference plane and a transition portion that slopes monotonically away from the reference plane.

24. The method of claim 18 wherein the lead frame has a proximal end mounted to the first die, a distal portion, a first surface, and a second surface opposite the first surface, the first and second surface extending between the proximal end and the distal portion, the method further comprising:
forming the first surface to have a convex portion and a concave portion, the convex portion being between the proximal end and the concave portion; and
forming the second surface to have a concave portion and a convex portion, the concave portion being between the proximal end and the convex portion.

25. The method of claim 18 wherein mounting the first die to the lead frame comprises aligning the lead frame with an interconnecting element on the first active face of the first die.

26. The method of claim 18, further comprising attaching a wirebond between the lead frame and the first die.

27. The method of claim 18, further comprising forming a ball grid array between the first and second dies.
